(19) United States
(12) Patent Application Publication
(10) Pub. No.: US 2024/0202388 A1
(43) Pub. Date: Jun. 20, 2024

(54) SYSTEMS AND METHODS FOR PERFORMING A SIMULATION USING DIFFERENT LEVELS OF FIDELITY

(71) Applicant: Disney Enterprises, Inc., Burbank, CA (US)

(72) Inventors: Patrick J. MCNAULL, Winter Garden, FL (US); Robert J. MARRA, Windermere, FL (US); Christopher C. HOFER, Ocoee, FL (US); Brian F. WALTERS, Groveland, FL (US)

(73) Assignee: Disney Enterprises, Inc., Burbank, CA (US)

(21) Appl. No.: 18/067,696

(22) Filed: Dec. 16, 2022

(51) Int. Cl. G06F 30/20

(52) U.S. Cl. CPC G06F 30/20

(57) ABSTRACT

In some implementations, a simulation platform may receive a request to perform a simulation of operations of a plurality of components. The simulation platform may receive first fidelity information identifying a first level of detail and functionality to be simulated for a first component of the plurality of components, wherein the first level of detail and functionality is part of a first plurality of levels of details and functionalities to be simulated for the first component. The simulation platform may receive second fidelity information identifying a second level of detail and functionality to be simulated for a second component of the plurality of components, wherein the second level of detail and functionality is part of a second plurality of levels of details and functionalities to be simulated for the second component. The simulation platform may execute, based on the request, a computer model to perform the simulation of the operations of the plurality of components, wherein, during the simulation, an operation of the first component is simulated based on the first fidelity information, and wherein, during the simulation, an operation of the second component is simulated based on the second fidelity information. The simulation platform may cause an action to be performed based on performing the simulation.

### BACKGROUND

A ride system includes a passenger vehicle that transports passengers through a ride experience. Typically, the passenger vehicle includes a system or device that propels the passenger vehicle through the ride experience, from one portion of the ride system to another portion of the ride system. In some situations, a computer model may be executed to simulate a movement of the passenger vehicle along a ride path.

### SUMMARY

In some implementations, a method performed by a simulation platform includes receiving a request to perform a simulation of operations of a plurality of components; receiving first fidelity information identifying a first level of detail and functionality to be simulated for a first component of the plurality of components, wherein the first level of detail and functionality is part of a first plurality of levels of details and functionalities to be simulated for the first component; receiving second fidelity information identifying a second level of detail and functionality to be simulated for a second component of the plurality of components, wherein the second level of detail and functionality is part of a second plurality of levels of details and functionalities to be simulated for the second component; executing, based on the request, a computer model to perform the simulation of the operations of the plurality of components, wherein, during the simulation, an operation of the first component is simulated based on the first fidelity information, and wherein, during the simulation, an operation of the second component is simulated based on the second fidelity information; and causing an action to be performed based on performing the simulation.

In some implementations, a device includes one or more processors configured to: receive first fidelity information identifying a first level of detail and functionality to be simulated for a component, wherein the first level of detail and functionality is part of a plurality of levels of details and functionalities to be simulated for the component; execute a computer model to perform a first simulation of an operation of the component, wherein, during the first simulation, the operation of the component is simulated based on the first fidelity information; receive, based on a result of performing the first simulation, second fidelity information identifying a second level of detail and functionality of the plurality of levels of details and functionalities, wherein the second level of detail and functionality is different than the first level of detail and functionality; and execute the computer model to perform a second simulation of the operation of the component, wherein, during the second simulation, the operation of the first component is simulated based on the second fidelity information.

In some implementations, a non-transitory computer-readable medium storing a set of instructions includes one or more instructions that, when executed by one or more processors of a device, cause the device to: receive first fidelity information identifying a first level of detail and functionality to be simulated for a component, wherein the first level of detail and functionality is part of a plurality of levels of details and functionalities to be simulated for the component; execute a computer model to perform a first simulation of an operation of the component, wherein, during the first simulation, the operation of the component is simulated based on the first fidelity information; receive, based on a result of performing the first simulation, second fidelity information identifying a second level of detail and functionality of the plurality of levels of details and functionalities, wherein the second level of detail and functionality is different than the first level of detail and functionality; and wherein, during the second simulation, the operation of the first component is simulated based on the second fidelity information.

### BRIEF DESCRIPTION OF THE DRAWINGS

FIGS. 1A-1H are diagrams of an example implementation described herein.

FIG. 2 is a diagram of an example environment in which systems and/or methods described herein may be implemented.

FIG. 3 is a diagram of example components of one or more devices of FIG. 2.

FIG. 4 is a flowchart of an example process relating to performing a simulation with different levels of fidelity.

### DETAILED DESCRIPTION

The following detailed description of example implementations refers to the accompanying drawings. The same reference numbers in different drawings may identify the same or similar elements.

A simulation environment may be a programming environment, of a computer, that is dedicated to simulations of different components (e.g., different systems and/or different objects). Software models of various components may be created to simulate functions, controls, physical constraints, and interactions within the simulation environment to aid in the design, testing, and operation of a physical environment.

Simulation environments are typically created using tools for creating models of physical components across multiple domains and at varying levels of fidelity. A “level of fidelity,” as used herein, may refer to a level of detail and functionality (e.g., for a component). Typically, the simulation environment is built for a particular purpose or for a narrow range of similar purposes. Additionally, the simulation environment typically models behaviors of all components, during a simulation, at a single level of fidelity.

As an example, a warehouse simulation may include models for boxes, shelves, pathways, and/or overhead cranes, among other examples. If the simulation is built for space planning at the warehouse, the models may have a low level of fidelity for attributes such as power requirements, outer dimensions, and/or weight, among other examples. A separate simulation would need to be created to model throughput or quality of service features that would require a higher level of fidelity, such as models that simulate operating speed, material composition, and/or maintenance status, among other examples.

In this regard, different use cases require separate simulations to be built for different levels of fidelity. Creating separate simulations is time consuming and expensive (e.g., computationally expensive), especially when each simulation include numerous components that are modeled. One solution (to the problem of creating separate simulations) may be to create a simulation with a highest level of fidelity possible. In this regard, a simulation developer may desire a first level of fidelity (e.g., a highest level of fidelity) for simulating an operation of a first component and desire a second level of fidelity (e.g., a lower or lowest level of fidelity) for simulating an operation of a second component. Because the operations of the components are typically simulated at the same level of fidelity, the simulation developer may cause operations of the components to be simulated at the first level of fidelity.

Typically, the simulation environment (and the simulation) becomes more complex as a level of detail (for modeling the components) increases. Accordingly, as the simulation environment becomes more complex, an amount of computing resources (for modeling the components) increases. In this regard, simulating the operations of the components at the first level of fidelity may consume a significant amount of computing resources. Because the first level of detail was not desired for the second component, simulating the operation of the second component at the first level of detail may unnecessarily consume a significant amount of computing resources. In other words, the computing resources used to simulate the operation of the second object at the first level of detail may be wasted.

Additionally to consuming a significant amount of computing resources, simulating the operations of the components at the first level of fidelity decrease a speed of execution of the simulation. Accordingly, simulating the operation of the second component at the first level of fidelity (instead of the second level of fidelity) unnecessarily decreases a speed of execution of the simulation for the operation of the second component.

Another solution (to resolve issues regarding creating separate simulations for different levels of fidelity) is to generate copies of a model with a component at a desired level of fidelity level. However, generating the copies in this manner is subject to errors. The errors may arise with respect to improperly synchronizing changes made to the model across all the copies of the mode. For instance, changes to the model may not replicated to all the copies or, alternatively, may be incorrectly replicated to all the copies. Improperly synchronizing the changes may result in inconsistent and/or inaccurate results of simulating an operation of the component.

Implementations described herein are directed to a simulation environment that supports modeling of operations of components at different levels of fidelity during a simulation. For example, during the simulation, a first component may be modeled at a first level of fidelity, a second component may be modeled at a second level of fidelity that is different than the first level of fidelity, and so on.

As used herein, the term “component” may refer to any machine or any device that may be modeled during a simulation in a simulation environment. In the context of an amusement park, the term “component” may refer to a passenger vehicle, a ride equipment, a show equipment, among other examples. A ride equipment may include sensor devices, braking equipment, among other examples. A show equipment may include light fixtures, animatronic figures, and/or robotic figures, among other examples.

As an example, with respect to an amusement park, when simulating a guest load and unload process, a model of a passenger vehicle, at a high level of fidelity, may be appropriate to account for operations of doors, safety systems, and human interaction. The high level of fidelity may be a level of fidelity that satisfies a threshold fidelity. Other components of the simulation (such as track switches, pacers, and/or brakes, among other examples) may not be relevant to the guest load and unload process. Accordingly, such components may be modeled in a level of fidelity that is less than the high level of fidelity. In this regard, by modeling components at different levels of variability during the simulation, computational overhead may be reduced.

A component may be modeled at different levels of fidelity to create a plurality of model components. One modeled component may be replaced with another modeled component in a simulation to meet a need for a particular task (or a particular use case). In other words, each modeled component (at a respective level of fidelity of the plurality of levels of fidelity) may be repurposed for different use cases. A codebase for the component may include different portions for each modeled component. Each portion of the codebase may be used for different use case.

As an example of replacements of a modeled component, a timing engine with a low level of fidelity and a timing engine with a high level of-fidelity may be interchangeable. In this regard, detailed timing (associated with the timing engine with the high level of-fidelity) can be used in some use cases while gross timing (associated with the timing engine with the low level of-fidelity) can be used in other use cases. The low level of fidelity may not satisfy the fidelity threshold while the high level fidelity satisfies the fidelity threshold.

As another example, ride equipment and passenger vehicles may be modelled with hardware in the loop capability for critical ride control simulation tasks while the ride equipment and the passenger vehicles may be modelled as simplified objects for many other tasks. By interchanging components as described herein, a speed of execution of a simulation is not reduced by unnecessary complex computations associated with the high level of fidelity when the high level of fidelity is not required for a component.

In some examples, a desired level of fidelity may be selected by providing fidelity information identifying the desired level of fidelity. The fidelity information may be provided via a user interface. In some situations, the fidelity information may be provided via option flags set at a beginning of the simulation and the user interface may be a command line interface. In other words, the fidelity information may be provided as arguments, of the command line interface, that are option flags.

Implementations described herein provide an ability to toggle an option flag to switch between different levels of fidelity for different components. The ability to toggle an option flag reduces the need to simulate operations of components at a same level of fidelity (e.g., at a high level of fidelity). Accordingly, the ability to toggle an option flag may prevent complex computations from being performed for a component that is to be modeled at a low level of fidelity. Therefore, the ability to toggle an option flag may reduce delays, during execution of the simulation, that would have been caused by the complex computations.

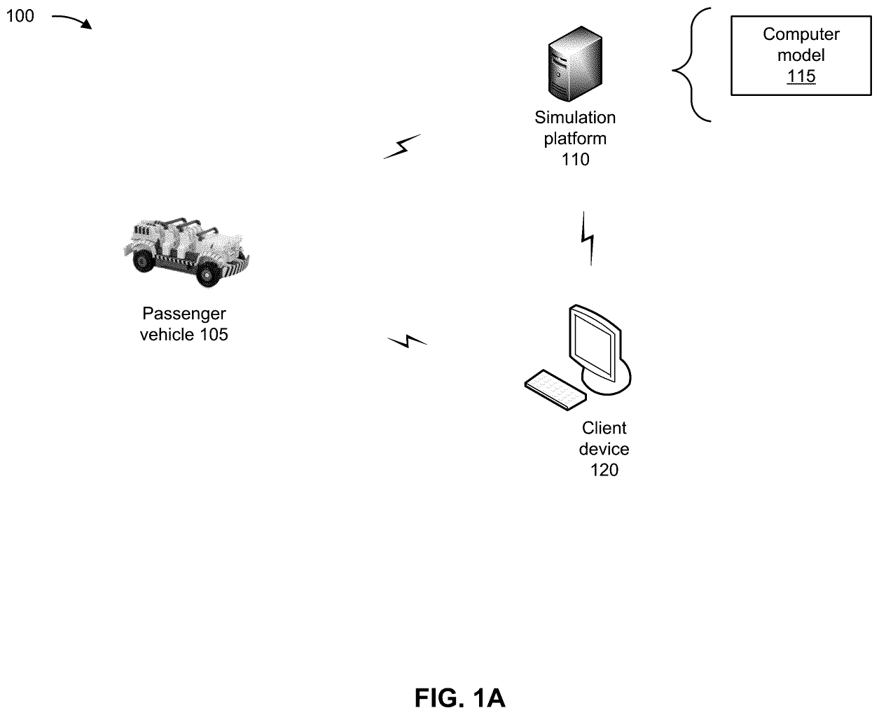

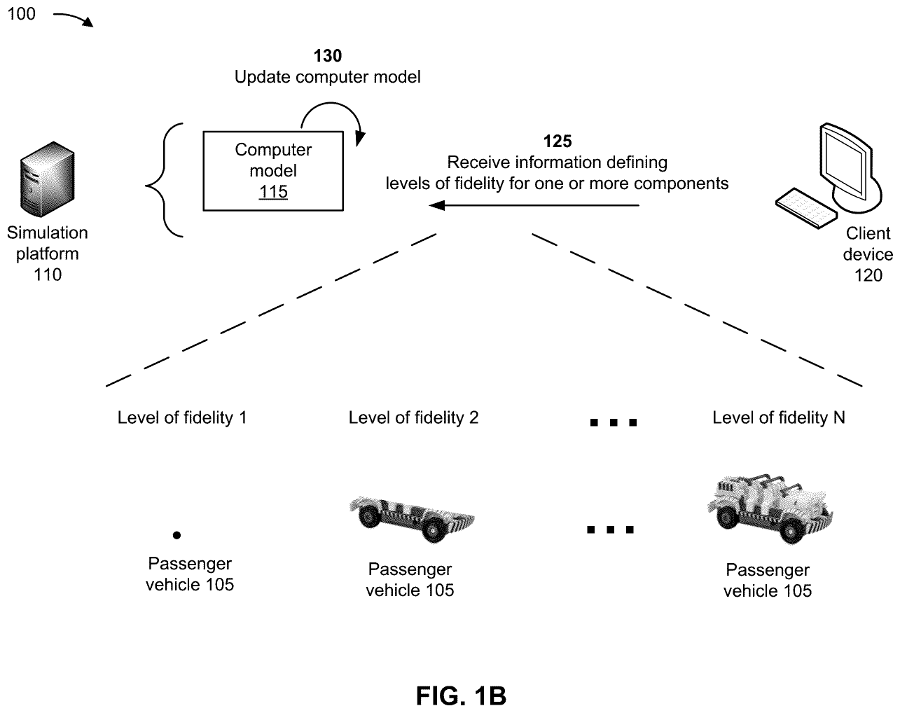

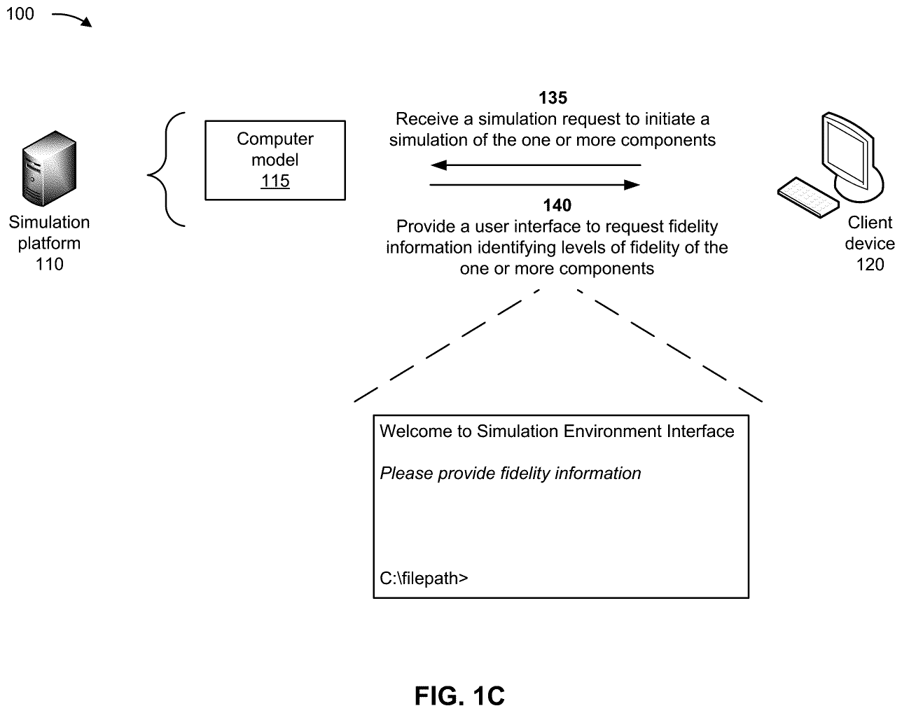

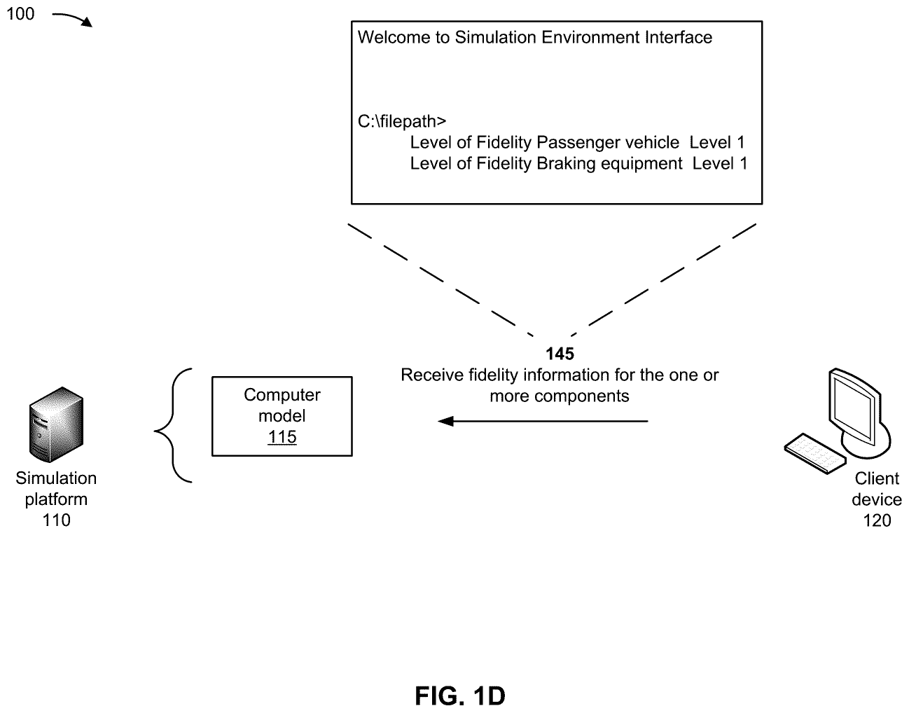

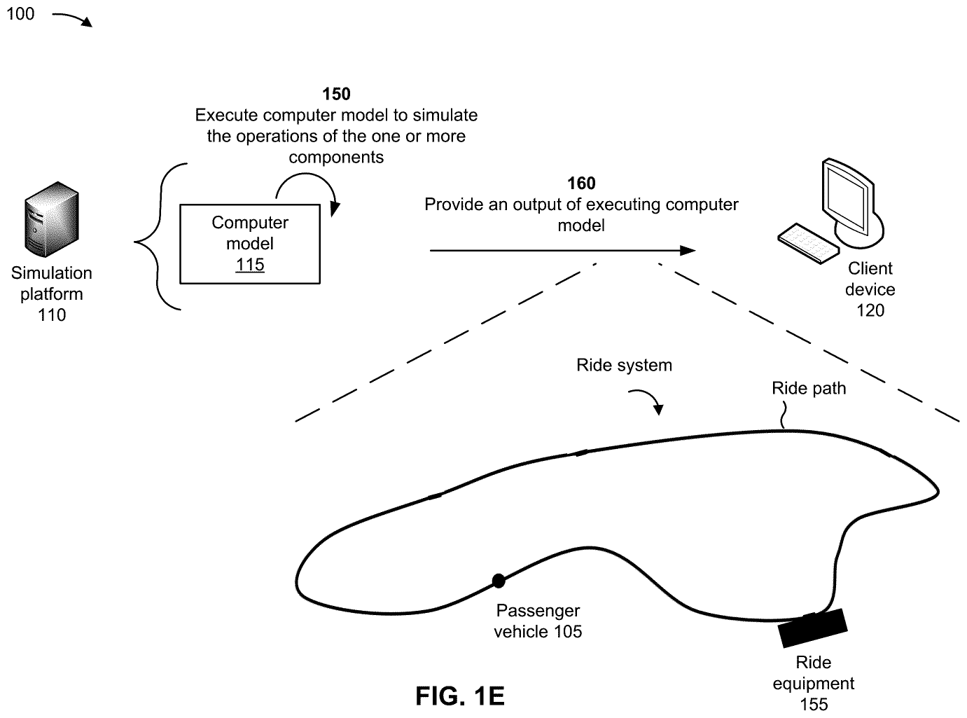

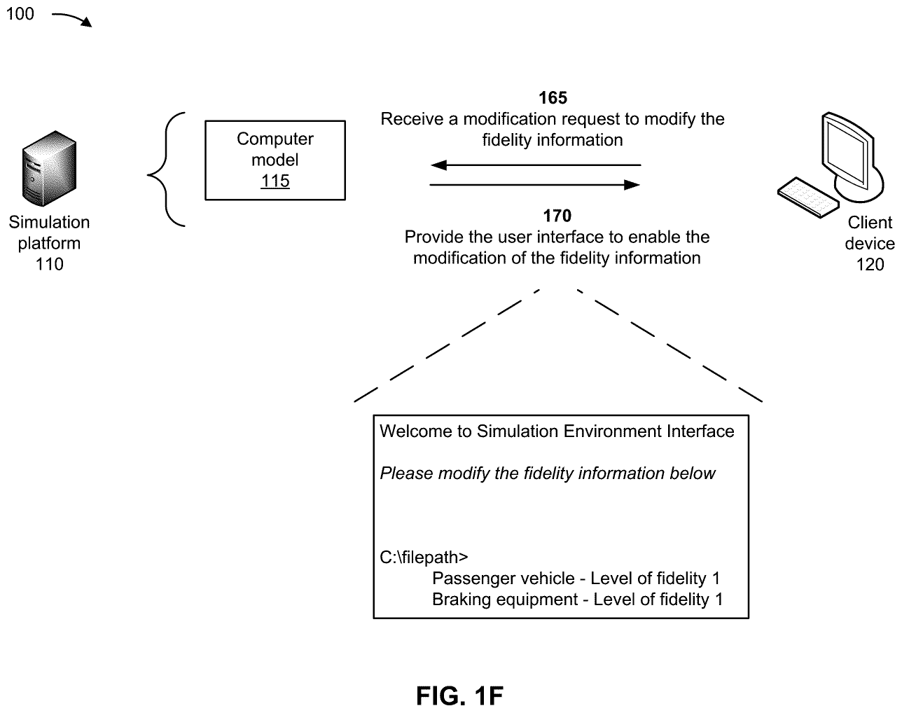

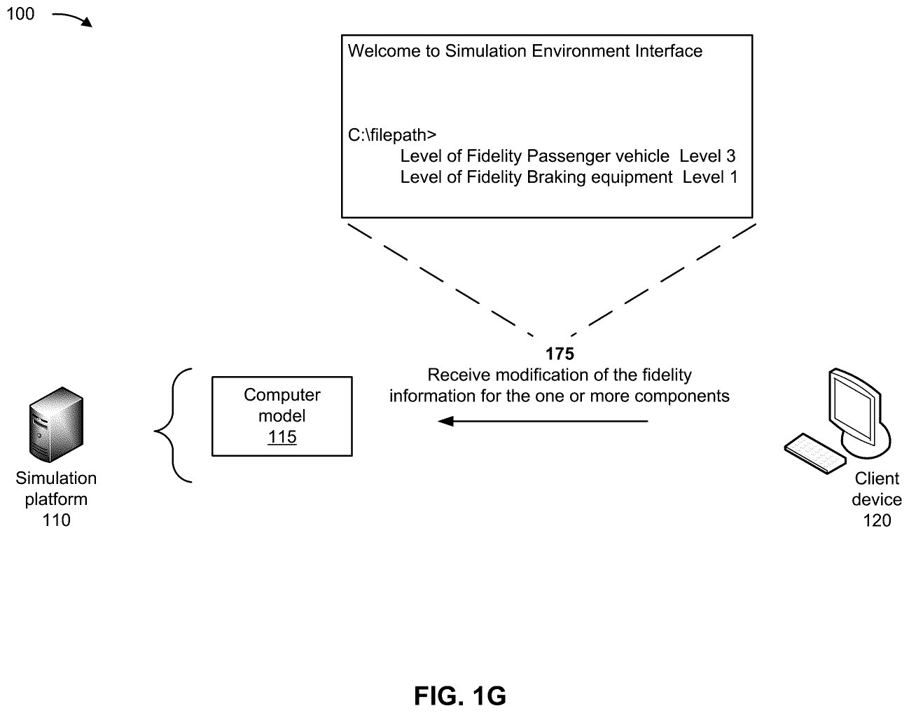

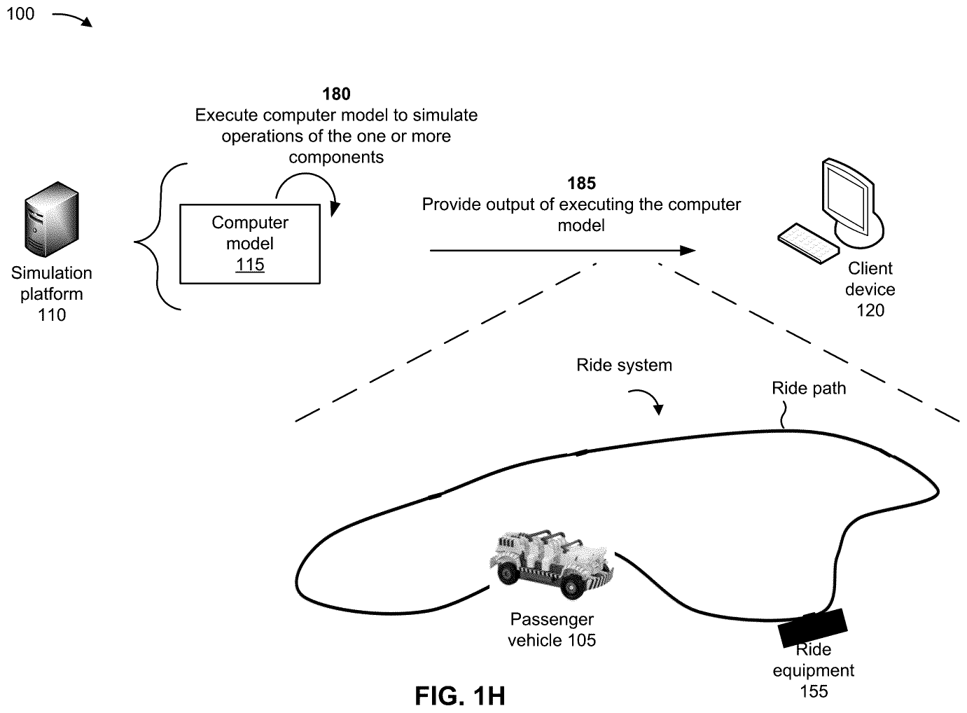

FIGS. 1A-1H are diagrams of an example implementation 100 associated with performing a simulation with different levels of fidelity. As shown in FIGS. 1A-1H, example implementation 100 includes a passenger vehicle 105, a simulation platform 110, and a client device 120. Passenger vehicle 105 may be configured to travel along a ride path of a ride system. In some examples, passenger vehicle 105 may be configured to interact with a ride equipment of the ride system. The Simulation platform 110 may include one or more devices configured to host a simulation environment. As shown in FIG. 1A, simulation platform 110 may include a computer model 115. Computer model 115 may include a computer model that is executed to a launch a simulation. For example, simulation platform 110 may be configured to execute computer model 115 to launch the simulation to simulate interactions between passenger vehicle 105 and the ride equipment. In some examples, the ride equipment may include a braking equipment.

Client device 120 may include one or more devices capable of capable of receiving, generating, storing, processing, and/or providing information associated with o performing a simulation with different levels of fidelity. Client device 120 may a device of a simulation developer, a modeler, a ride operator, and/or a system administrator, among other examples.

Client device 120 may be capable of receiving (e.g., from simulation platform 110) outputs of the simulation (e.g., thousands of outputs) and provide the outputs for display (e.g., to the simulation developer, to the modeler of computer model 115, to an individual associated with client device 120, among other examples). In some implementations, client device 120 may be configured to execute computer model 115 in a manner similar to a manner in which simulation platform 110 executes computer model 115.

In some implementations, ride equipment 155 may include braking equipment. In this regard, the braking equipment may be configured to apply an amount of braking force on passenger vehicle 125. The braking equipment may be configured to apply the amount of braking force on passenger vehicle 125 based on an interaction between the braking equipment and passenger vehicle 125. In some implementations, ride equipment 155 and passenger vehicle 125 may be provided in an experimental setting (e.g., provided in a lab setting).

As shown in FIG. 1B, and by reference number 125, simulation platform 110 may receive information defining levels of fidelity for one or more components. A simulation developer may desire to define the levels of fidelity for the one or more components that are to be modeled. Accordingly, the simulation developer may use client device 120 to define the levels of fidelity for the one or more components and cause client device 120 to provide the information defining the levels of fidelity to simulation platform 110. The simulation developer may define the levels of fidelity using a user interface. In some implementations, the user interface may include a command line interface.

As shown in FIG. 1B, as an example, different levels of fidelity may be defined for passenger vehicle 105. For example, information defining a first level of fidelity (or level of fidelity 1) may indicate that passenger vehicle 105 (as modeled) is to simply move at a particular velocity. The first level of fidelity may not account for propulsion system of passenger vehicle 105 (e.g., wheels, engine, transmission, among other examples). Information defining a second level of fidelity (or level of fidelity 2) may define the propulsion system of passenger vehicle 105 along with the particular velocity at which passenger vehicle 105 is traveled (as modeled). Information defining a third level of fidelity may define an operation of an engine of passenger vehicle 105 along with the propulsion system and the particular velocity. The operation of the engine may include a current generated by the engine, an amount of mechanical generated by the engine, among other examples.

Information defining a fourth level of fidelity may define an operation of a braking system of passenger vehicle 105 and an operation of a lighting system of passenger vehicle 105. Additional information for additional levels of fidelity may define additional granular operations of passenger vehicle 105. For example, the additional information for the additional levels of fidelity may define an operation of a battery system of passenger vehicle 105, an operation of an electrical system of passenger vehicle 105, an operation of a hydraulic system of passenger vehicle 105,

The information regarding the different levels of fidelity may be used to model an operation of different elements of passenger vehicle 105 during a simulation involving passenger vehicle 105. The information regarding the different levels of fidelity may be part of a codebase of passenger vehicle 105. Each portion of the codebase may correspond to a different level of fidelity.

While the different levels of fidelity have been described with respect to passenger vehicle 105, implementations described are applicable to defining different of levels of fidelity for other components, such as ride equipment 135, show equipment, among other examples. With respect to ride equipment 135, the simulation developer may define different levels of fidelity for an operation of braking equipment, define different levels of fidelity for an operation of a sensor device, define different levels of fidelity for an operation of a ride controller, among other examples. With respect to show equipment, the simulation developer may define different levels of fidelity for an operation of a lighting fixture, define different levels of fidelity for an operation of a speaker system, define different levels of fidelity for an operation of an animatronic figure, among other examples.

As shown in FIG. 1B, and by reference number 130, simulation platform 110 may update computer model 115. For example, simulation platform 110 may update a library of codes of computer model 115 to include the codebase for each component of the one or more components. The library of codes may be stored in one or more memories associated with simulation platform 110

As shown in FIG. 1C, and by reference number 135, simulation platform 110 may receive a simulation request to initiate a simulation of the one or more components. For example, after the library of codes of computer model 115 has been updated to include the codebase for each component of the one or more components, simulation platform 110 may receive the simulation request from client device 120. For example, the simulation developer to desire simulate the operations of the one or more components. For instance, the simulation developer may desire to test the information regarding the different levels of fidelity. Accordingly, the simulation developer may use client device 120 to provide the simulation request.

As shown in FIG. 1C, and by reference number 140, simulation platform 110 may provide a user interface to request fidelity information identifying levels of fidelity of the one or more components. For example, based on the simulation request, simulation platform 110 may provide a user interface and may prompt, the simulation developer, for the fidelity information. In some examples, the user interface may be a command line interface.

As shown in FIG. 1D, and by reference number 145, simulation platform 110 may receive fidelity information for the one or more components. For example, based on providing the user interface, simulation platform 110 may receive the fidelity information via the user interface. In situations where the user interface is the command line interface, simulation platform 110 may receive the fidelity information in the form of command line arguments. In some examples, simulation platform 110 may receive the fidelity information as option flags indicating levels of fidelity desired by the simulation developer for the one or more components.

As shown in FIG. 1D, client device 120 may provide first fidelity information for passenger vehicle 105 and provide second fidelity information for ride equipment 155. As shown in FIG. 1D, the first fidelity information may indicate that the level of fidelity for passenger vehicle 105 is level 1 and that the second fidelity information may indicate that the level of fidelity for ride equipment 155 is level 1. In some situations, because passenger vehicle 105 and ride equipment 155 are different components, the level 1 for the level of fidelity may be indicate different levels of granularity with respect to the operations of passenger vehicle 105 and ride equipment 155.

As shown in FIG. 1E, and by reference number 150, simulation platform 110 may execute computer model 115 to simulate the operations of the one or more components. For example, after receiving the fidelity information from client device 120, simulation platform 110 may execute computer model 115 based on the fidelity information. Simulation platform 110 may execute computer model 115 to perform a first simulation of the operations of passenger vehicle 105 and ride equipment 155. In some implementations, based on the first fidelity information, simulation platform 110 may identify a portion of the codebase for passenger vehicle 105 corresponding to the first level of fidelity defined for passenger vehicle 105. Similarly, based on the second fidelity information, simulation platform 110 may identify a portion of a codebase for ride equipment 155 corresponding to the first level of fidelity defined for ride equipment 155.

Simulation platform 110 may execute computer model 115 based on the portion of the codebase for passenger vehicle 105 (corresponding to the first level of fidelity defined for passenger vehicle 105) and based on the portion of the codebase for ride equipment 155 (corresponding to the first level of fidelity defined for ride equipment 155). In this regard, simulation platform 110 may simulate the operations indicated by the first level of fidelity defined for passenger vehicle 105 and indicated by the first level of fidelity defined for ride equipment 155. For example, with respect to the first level of fidelity defined for passenger vehicle 105, simulation platform 110 may simulate passenger vehicle 105 moving at the particular velocity.

As shown in FIG. 1E, and by reference number 160, simulation platform 110 may provide an output of executing computer model 115. For example, simulation platform 110 may provide an output of simulating the operations of passenger vehicle 105 and ride equipment 155.

As shown in FIG. 1F, and by reference number 165, simulation platform 110 may receive a modification request to modify the fidelity information of the one or more components. In some examples, the simulation developer may desire for one or more additional levels of fidelity for the operation of passenger vehicle 105. Additionally, or alternatively, the simulation developer may detect an issue regarding the movement of passenger vehicle 105.

Additionally, or alternatively, simulation platform 110 may detect an issue regarding the movement of passenger vehicle 105. In this regard, client device 120 may provide the modification request based on the desire for the additional levels of fidelity and/or based on detecting an issue regarding the movement of passenger vehicle 105.

As shown in FIG. 1F, and by reference number 170, simulation platform 110 may provide the user interface to enable the modification of the fidelity information. For example, simulation platform 110 may provide the user interface in manner similar to the manner described in connection with FIG. 1C.

As shown in FIG. 1G, and by reference number 175, simulation platform 110 may receive the modification of the fidelity information for the one or more components. For example, simulation platform 110 may receive the modification in manner similar to the manner described above in FIG. 1D in connection with receiving the fidelity information. As shown in FIG. 1G, client device 120 may modify the level of fidelity of passenger vehicle 105 from the first level of fidelity to the third level of fidelity. For example, simulation platform 110 may receive the third fidelity information identifying the third level of fidelity.

As shown in FIG. 1H, and by reference number 180, simulation platform 110 may execute computer model 115 to simulate the operation of the one or more components. For example, simulation platform 110 may execute computer model 115 in a manner similar to the manner described above in connection with FIG. 1E. Simulation platform 110 may execute computer model 115 to perform a second simulation. In some implementations, based on the third fidelity information, simulation platform 110 may identify a portion of the codebase for passenger vehicle 105 corresponding to the third level of fidelity defined for passenger vehicle 105.

As shown in FIG. 1H, and by reference number 185, simulation platform 110 may provide an output of executing computer model 115. For example, simulation platform 110 may provide an output of simulating the operations of passenger vehicle 105 and ride equipment 155.

Implementations described herein are directed to a simulation environment that supports pluggable modeled components associated with variable levels of fidelity. The modeled components may be interchanged to allow use of a least capable modeled component (e.g., associated with a lowest level of fidelity) to support a given task. In a single simulation, modeled components of disparate levels of fidelity can be operated so that computational resources are flexibly and efficiently allocated to areas of interest.

The simulation environment becomes a versatile tool that can be used throughout the design and operation of an attraction, from physics-based pre-visualization during show design, to complicated ride software programming, to operational analysis and maintenance. Moreover, a data model used herein enables simulated ride control models to be interchanged with physical hardware ride control for hardware in the loop simulation without recreating an entire simulation environment.

As explained herein, different portions of a codebase of a component may correspond to different levels of fidelity of the component. Each portion of the codebase may be used for a variety of use cases. Using the different portions of the codebase in this manner yields a time savings when setting up the modeled component to run at a desired level of fidelity. The different levels of fidelity may be selected via different option flags that can be provided, via a user interface, to control the behavior of the simulation, rather than commenting in and/or out code or making a separate copy of the modeled component. The number and influence of the option flags may be completely customizable to fit a specific use case of the simulation. Having localized control over the level of fidelity also reduces a computation time required to run the simulation as more complex operations can be abstracted away in many use cases.

As indicated above, FIGS. 1A-1H are provided as an example. Other examples may differ from what is described with regard to FIGS. 1A-1H. The number and arrangement of devices shown in FIGS. 1A-1H are provided as an example. In practice, there may be additional devices, fewer devices, different devices, or differently arranged devices than those shown in FIGS. 1A-1H. Furthermore, two or more devices shown in FIGS. 1A-1H may be implemented within a single device, or a single device shown in FIGS. 1A-1H may be implemented as multiple, distributed devices. Additionally, or alternatively, a set of devices (e.g., one or more devices) shown in FIGS. 1A-1H may perform one or more functions described as being performed by another set of devices shown in FIGS. 1A-1H.

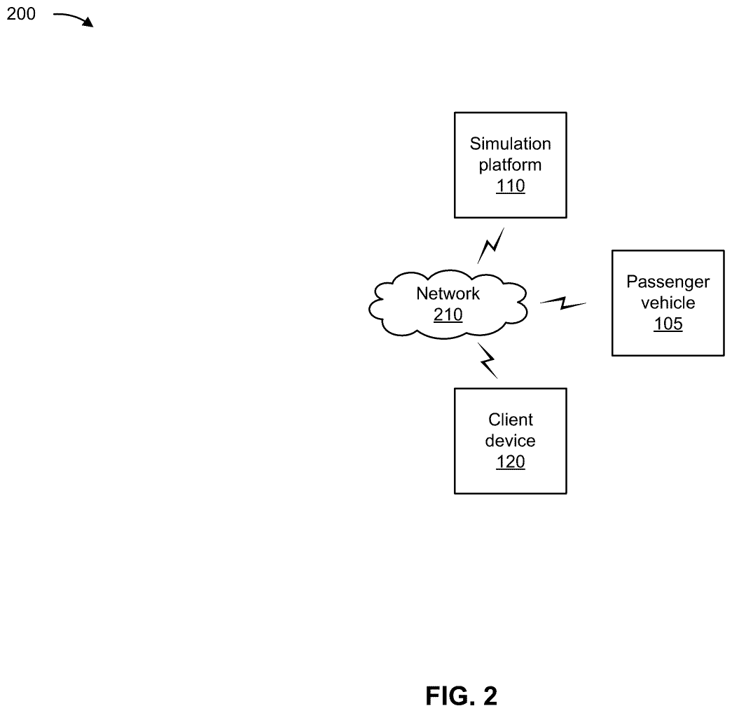

FIG. 2 is a diagram of an example environment 200 in which systems and/or methods described herein may be implemented. Some elements of environment 200 have been described above in connection with FIG. 1. In some implementations, simulation platform 110 may include one or more elements of and/or may execute within a cloud computing system. As further shown in FIG. 2, environment 200 may include passenger vehicle 105, client device 120, ride equipment 155, and/or a network 210. In some implementations, ride equipment 155 and passenger vehicle 125 may be provided in an experimental setting (e.g., provided in a lab setting). Devices and/or elements of environment 200 may interconnect via wired connections and/or wireless connections.

In some situations, simulation platform 110 may include a server, such as an application server, a client server, a web server, a database server, a host server, a proxy server, a virtual server (e.g., executing on computing hardware), or a server in a cloud computing system. In some implementations, simulation platform 110 includes computing hardware used in a cloud computing environment.

Client device 120 includes one or more devices capable of receiving, generating, storing, processing, and/or providing performing a simulation with different levels of fidelity. Client device 120 may include a communication device and a computing device. For example, client device 120 may include a wireless communication device, a mobile phone, a user equipment, a laptop computer, a tablet computer, a desktop computer, or a similar type of device.

Network 210 includes one or more wired and/or wireless networks. For example, network 210 may include a cellular network, a public land mobile network (PLMN), a local area network (LAN), a wide area network (WAN), a private network, the Internet, and/or a combination of these or other types of networks. The network 210 enables communication among the devices of environment 200.

The number and arrangement of devices and networks shown in FIG. 2 are provided as an example. In practice, there may be additional devices and/or networks, fewer devices and/or networks, different devices and/or networks, or differently arranged devices and/or networks than those shown in FIG. 2. Furthermore, two or more devices shown in FIG. 2 may be implemented within a single device, or a single device shown in FIG. 2 may be implemented as multiple, distributed devices. Additionally, or alternatively, a set of devices (e.g., one or more devices) of environment 200 may perform one or more functions described as being performed by another set of devices of environment 200.

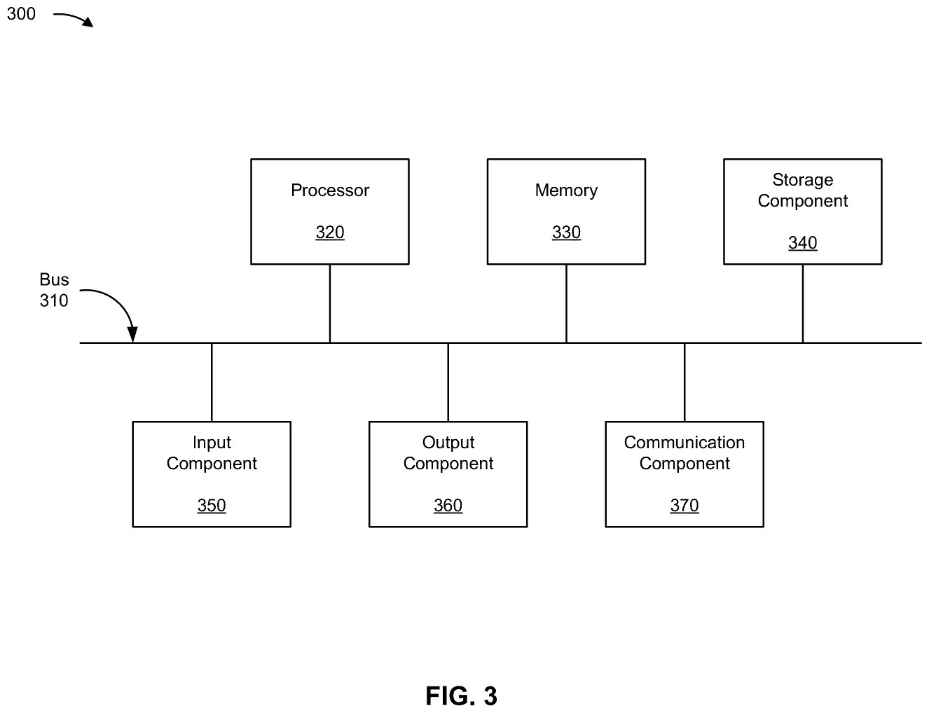

FIG. 3 is a diagram of example components of a device 300, which may correspond to simulation platform 110 and/or client device 120. In some implementations, simulation platform 110 and/or client device 120 may include one or more devices 300 and/or one or more components of device 300. As shown in FIG. 3, device 300 may include a bus 310, a processor 320, a memory 330, a storage component 340, an input component 350, an output component 360, and a communication component 370.

Bus 310 includes a component that enables wired and/or wireless communication among the components of device 300. Processor 320 includes a central processing unit, a graphics processing unit, a microprocessor, a controller, a microcontroller, a digital signal processor, a field-programmable gate array, an application-specific integrated circuit, and/or another type of processing component. Processor 320 is implemented in hardware, firmware, or a combination of hardware and software. In some implementations, processor 320 includes one or more processors capable of being programmed to perform a function. Memory 330 includes a random access memory, a read only memory, and/or another type of memory (e.g., a flash memory, a magnetic memory, and/or an optical memory).

Storage component 340 stores information and/or software related to the operation of device 300. For example, storage component 340 may include a hard disk drive, a magnetic disk drive, an optical disk drive, a solid state disk drive, a compact disc, a digital versatile disc, and/or another type of non-transitory computer-readable medium. Input component 350 enables device 300 to receive input, such as user input and/or sensed inputs. For example, input component 350 may include a touch screen, a keyboard, a keypad, a mouse, a button, a microphone, a switch, a sensor, a global positioning system component, an accelerometer, a gyroscope, and/or an actuator. Output component 360 enables device 300 to provide output, such as via a display, a speaker, and/or one or more light-emitting diodes. Communication component 370 enables device 300 to communicate with other devices, such as via a wired connection and/or a wireless connection. For example, communication component 370 may include a receiver, a transmitter, a transceiver, a modem, a network interface card, and/or an antenna.

Device 300 may perform one or more processes described herein. For example, a non-transitory computer-readable medium (e.g., memory 330 and/or storage component 340) may store a set of instructions (e.g., one or more instructions, code, software code, and/or program code) for execution by processor 320. Processor 320 may execute the set of instructions to perform one or more processes described herein. In some implementations, execution of the set of instructions, by one or more processors 320, causes the one or more processors 320 and/or the device 300 to perform one or more processes described herein. In some implementations, hardwired circuitry may be used instead of or in combination with the instructions to perform one or more processes described herein. Thus, implementations described herein are not limited to any specific combination of hardware circuitry and software.

The number and arrangement of components shown in FIG. 3 are provided as an example. Device 300 may include additional components, fewer components, different components, or differently arranged components than those shown in FIG. 3. Additionally, or alternatively, a set of components (e.g., one or more components) of device 300 may perform one or more functions described as being performed by another set of components of device 300.

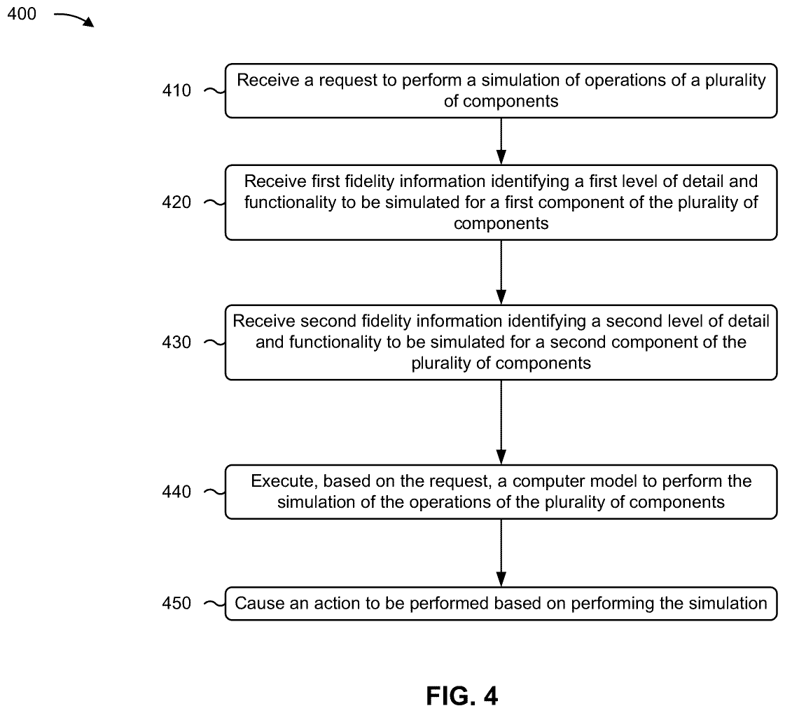

FIG. 4 is a flowchart of an example process 400 associated with systems and methods for pre-calculating information regarding interactions between objects during a simulation.

In some implementations, one or more process blocks of FIG. 4 may be performed by a simulation platform (e.g., simulation platform 110). In some implementations, one or more process blocks of FIG. 4 may be performed by another device or a group of devices separate from or including the simulation platform, such as a client device (e.g., client device 120). Additionally, or alternatively, one or more process blocks of FIG. 4 may be performed by one or more components of device 300, such as processor 320, memory 330, storage component 340, input component 350, output component 360, and/or communication component 370.

As shown in FIG. 4, process 400 may include receiving a request to perform a simulation of operations of a plurality of components (block 410). For example, the simulation platform may receive a request to perform a simulation of operations of a plurality of components, as described above.

As further shown in FIG. 4, process 400 may include receiving first fidelity information identifying a first level of detail and functionality to be simulated for a first component of the plurality of components (block 420). For example, the simulation platform may receive first fidelity information identifying a first level of detail and functionality to be simulated for a first component of the plurality of components, wherein the first level of detail and functionality is part of a first plurality of levels of details and functionalities to be simulated for the first component, as described above. In some implementations, the first level of detail and functionality is part of a first plurality of levels of details and functionalities to be simulated for the first component.

As further shown in FIG. 4, process 400 may include receiving second fidelity information identifying a second level of detail and functionality to be simulated for a second component of the plurality of components (block 430). For example, the simulation platform may receive second fidelity information identifying a second level of detail and functionality to be simulated for a second component of the plurality of components, wherein the second level of detail and functionality is part of a second plurality of levels of details and functionalities to be simulated for the second component, as described above. In some implementations, the second level of detail and functionality is part of a second plurality of levels of details and functionalities to be simulated for the second component.

As further shown in FIG. 4, process 400 may include executing, based on the request, a computer model to perform the simulation of the operations of the plurality of components (block 440). For example, the simulation platform may execute, based on the request, a computer model to perform the simulation of the operations of the plurality of components, wherein, during the simulation, an operation of the first component is simulated based on the first fidelity information, and wherein, during the simulation, an operation of the second component is simulated based on the second fidelity information, as described above.

As further shown in FIG. 4, process 400 may include causing an action to be performed based on performing the simulation (block 450). For example, the simulation platform may cause an action to be performed based on performing the simulation, as described above.

In some implementations, the first level of detail and functionality exceeds the second level of detail and functionality.

In some implementations, the first component is a passenger vehicle, and wherein the second component is ride equipment of a ride system, and wherein the simulation is a simulation of an interaction between the passenger vehicle and the ride equipment as the passenger vehicle moves along a path of the ride system.

In some implementations, process 400 includes providing a user interface, wherein receiving the first fidelity information comprises receiving the first fidelity information via the user interface, and wherein receiving the second fidelity information comprises receiving the second fidelity information via the user interface.

In some implementations, the simulation is a first simulation, and wherein causing the action to be performed comprises receiving, after performing the first simulation, third fidelity information identifying a third level of detail and functionality of the first plurality of levels of details and functionalities, and executing the computer model to perform a second simulation of the operations of the plurality of components, wherein, during the second simulation, the operation of the first component is simulated based on the third fidelity information.

In some implementations, causing the action to be performed comprises detecting an issue regarding the movement of the passenger vehicle, and receiving the third fidelity information based on detecting the issue, wherein executing the computer model to perform the second simulation of the operations of the plurality of components comprises executing the computer model to perform the second simulation to resolve the issue.

In some implementations, the first component is a passenger vehicle of a ride system, and wherein executing the computer model to perform the first simulation comprises simulating a movement of the passenger vehicle along a path of the ride system, and wherein executing the computer model to perform the second simulation comprises simulating the movement of the passenger vehicle along the path of the ride system based on one or more of a mass of the passenger vehicle, an electrical configuration of the passenger vehicle, a mechanical configuration of the passenger vehicle, or a hydraulic configuration of the passenger vehicle.

Although FIG. 4 shows example blocks of process 400, in some implementations, process 400 may include additional blocks, fewer blocks, different blocks, or differently arranged blocks than those depicted in FIG. 4. Additionally, or alternatively, two or more of the blocks of process 400 may be performed in parallel.

The foregoing disclosure provides illustration and description, but is not intended to be exhaustive or to limit the implementations to the precise forms disclosed. Modifications may be made in light of the above disclosure or may be acquired from practice of the implementations.

As used herein, the term “component” is intended to be broadly construed as hardware, firmware, or a combination of hardware and software. It will be apparent that systems and/or methods described herein may be implemented in different forms of hardware, firmware, and/or a combination of hardware and software. The actual specialized control hardware or software code used to implement these systems and/or methods is not limiting of the implementations. Thus, the operation and behavior of the systems and/or methods are described herein without reference to specific software code—it being understood that software and hardware can be used to implement the systems and/or methods based on the description herein.

Although particular combinations of features are recited in the claims and/or disclosed in the specification, these combinations are not intended to limit the disclosure of various implementations. In fact, many of these features may be combined in ways not specifically recited in the claims and/or disclosed in the specification. Although each dependent claim listed below may directly depend on only one claim, the disclosure of various implementations includes each dependent claim in combination with every other claim in the claim set. As used herein, a phrase referring to “at least one of” a list of items refers to any combination of those items, including single members. As an example, “at least one of: a, b, or c” is intended to cover a, b, c, a-b, a-c, b-c, and a-b-c, as well as any combination with multiple of the same item.

No element, act, or instruction used herein should be construed as critical or essential unless explicitly described as such. Also, as used herein, the articles “a” and “an” are intended to include one or more items, and may be used interchangeably with “one or more.” Further, as used herein, the article “the” is intended to include one or more items referenced in connection with the article “the” and may be used interchangeably with “the one or more.” Furthermore, as used herein, the term “set” is intended to include one or more items (e.g., related items, unrelated items, or a combination of related and unrelated items), and may be used interchangeably with “one or more.” Where only one item is intended, the phrase “only one” or similar language is used. Also, as used herein, the terms “has,” “have,” “having,” or the like are intended to be open-ended terms. Further, the phrase “based on” is intended to mean “based, at least in part, on” unless explicitly stated otherwise. Also, as used herein, the term “or” is intended to be inclusive when used in a series and may be used interchangeably with “and/or,” unless explicitly stated otherwise (e.g., if used in combination with “either” or “only one of”).

What is claimed is:

1. A method performed by a simulation platform, the method comprising:
receiving a request to perform a simulation of operations of a plurality of components;
receiving first fidelity information identifying a first level of detail and functionality to be simulated for a first component of the plurality of components,
wherein the first level of detail and functionality is part of a first plurality of levels of details and functionalities to be simulated for the first component;
receiving second fidelity information identifying a second level of detail and functionality to be simulated for a second component of the plurality of components,
wherein the second level of detail and functionality is part of a second plurality of levels of details and functionalities to be simulated for the second component;
executing, based on the request, a computer model to perform the simulation of the operations of the plurality of components,
wherein, during the simulation, an operation of the first component is simulated based on the first fidelity information, and
wherein, during the simulation, an operation of the second component is simulated based on the second fidelity information; and
causing an action to be performed based on performing the simulation.

2. The method of claim 1, wherein the first level of detail and functionality exceeds the second level of detail and functionality.

3. The method of claim 2, wherein the first component is a passenger vehicle, and
wherein the second component is ride equipment of a ride system, and
wherein the simulation is a simulation of an interaction between the passenger vehicle and the ride equipment as the passenger vehicle moves along a path of the ride system.

4. The method of claim 1, further comprising:
providing a user interface,
wherein receiving the first fidelity information comprises receiving the first fidelity information via the user interface, and
wherein receiving the second fidelity information comprises receiving the second fidelity information via the user interface.

5. The method of claim 1, wherein the simulation is a first simulation, and
wherein causing the action to be performed comprises:
receiving, after performing the first simulation, third fidelity information identifying a third level of detail and functionality of the first plurality of levels of details and functionalities; and
executing the computer model to perform a second simulation of the operations of the plurality of components,
wherein, during the second simulation, the operation of the first component is simulated based on the third fidelity information.

6. The method of claim 5, wherein causing the action to be performed comprises:
detecting an issue regarding the movement of the passenger vehicle; and
receiving the third fidelity information based on detecting the issue,
wherein executing the computer model to perform the second simulation of the operations of the plurality of components comprises executing the computer model to perform the second simulation to resolve the issue.

7. The method of claim 5, wherein the first component is a passenger vehicle of a ride system, and
wherein executing the computer model to perform the first simulation comprises:
simulating a movement of the passenger vehicle along a path of the ride system, and
wherein executing the computer model to perform the second simulation comprises:
simulating the movement of the passenger vehicle along the path of the ride system based on one or more of a mass of the passenger vehicle, an electrical configuration of the passenger vehicle, a mechanical configuration of the passenger vehicle, or a hydraulic configuration of the passenger vehicle.

8. A device, comprising:
one or more processors configured to:
receive first fidelity information identifying a first level of detail and functionality to be simulated for a component,
wherein the first level of detail and functionality is part of a plurality of levels of details and functionalities to be simulated for the component;
execute a computer model to perform a first simulation of an operation of the component,
wherein, during the first simulation, the operation of the component is simulated based on the first fidelity information;
receive, based on a result of performing the first simulation, second fidelity information identifying a second level of detail and functionality of the plurality of levels of details and functionalities,
wherein the second level of detail and functionality is different than the first level of detail and functionality; and
execute the computer model to perform a second simulation of the operation of the component,
wherein, during the second simulation, the operation of the first component is simulated based on the second fidelity information.

9. The device of claim 8, wherein the one or more processors are further configured to:
provide a user interface;
receive the first fidelity information via the user interface; and
receive the second fidelity information via the user interface.

10. The device of claim 8, wherein the user interface includes a command line interface,
wherein the first fidelity information includes a first option flag, and
wherein the first fidelity information includes a second option flag.

11. The device of claim 8, wherein the first level of detail and functionality exceeds the second level of detail and functionality.

12. The device of claim 11, wherein the component is a passenger vehicle, and
wherein the first simulation is a simulation of a movement of the passenger vehicle along a path of a ride system.

13. The device of claim 12, wherein the second simulation is a simulation of one or more of a mechanical operation of the passenger vehicle during the movement of the passenger vehicle, an electrical operation of the passenger vehicle during the movement of the passenger vehicle, or a hydraulic operation of the passenger vehicle during the movement of the passenger vehicle.

14. The device of claim 8, wherein the component is a first component,
wherein the plurality of levels of details and functionalities are a first plurality of levels of details and functionalities, and
wherein the one or more processors are further configured to:
receive third fidelity information identifying a third level of detail and functionality to be simulated for a second component of the plurality of components,
wherein the third level of detail and functionality is part of a second plurality of levels of details and functionalities to be simulated for the second component, and
wherein, during the first simulation, an operation of the second component is simulated based on the third fidelity information.

15. A non-transitory computer-readable medium storing a set of instructions, the set of instructions comprising:
one or more instructions that, when executed by one or more processors of a device, cause the device to:
receive first fidelity information identifying a first level of detail and functionality to be simulated for a component,
wherein the first level of detail and functionality is part of a plurality of levels of details and functionalities to be simulated for the component;
execute a computer model to perform a first simulation of an operation of the component,
wherein, during the first simulation, the operation of the component is simulated based on the first fidelity information;
receive, based on a result of performing the first simulation, second fidelity information identifying a second level of detail and functionality of the plurality of levels of details and functionalities,
wherein the second level of detail and functionality is different than the first level of detail and functionality; and
wherein, during the second simulation, the operation of the first component is simulated based on the second fidelity information.

16. The non-transitory computer-readable medium of claim 15, wherein the one or more instructions further cause the device to:
provide a user interface;
receive the first fidelity information via the user interface; and
receive the second fidelity information via the user interface.

17. The non-transitory computer-readable medium of claim 16, wherein the component is a passenger vehicle, and
wherein the first simulation is a simulation of a movement of the passenger vehicle along a path of a ride system.

18. The non-transitory computer-readable medium of claim 17, wherein the second level of detail and functionality exceeds the first level of detail and functionality. and
wherein the second simulation is a simulation of one or more of a mechanical operation of the passenger vehicle during the movement of the passenger vehicle, an electrical operation of the passenger vehicle during the movement of the passenger vehicle, or a hydraulic operation of the passenger vehicle during the movement of the passenger vehicle.

19. The non-transitory computer-readable medium of claim 15, wherein the component is a passenger vehicle, and
wherein the one or more instructions further cause the device to:
detect an issue regarding a movement of the passenger vehicle;
receive the second fidelity information based on detecting the issue; and
execute the computer model to perform the second simulation to resolve the issue.

20. The non-transitory computer-readable medium of claim 15, wherein the component is a first component,
wherein the plurality of levels of details and functionalities are a first plurality of levels of details and functionalities to be simulated for the first component, and
wherein the one or more instructions further cause the device to:
receive third fidelity information identifying a third level of detail and functionality to be simulated for a second component of the plurality of components,
wherein the third level of detail and functionality is part of a second plurality of levels of details and functionalities to be simulated for the second component, and
wherein, during the first simulation, an operation of the second component is simulated based on the third fidelity information.
